(19) United States
(12) Patent Application Publication
(10) Pub. No.: US 2002/0125551 A1
(43) Pub. Date: Sep. 12, 2002

(54) Micro bubble grid array semiconductor package

(76) Inventor: Kuo-Ning Chiang, Tao-Yen (TW)

Correspondence Address: Hung Chang LIN, 8 Schindler Court, Silver Spring, MD, 20903, US

(21) Appl. No.: 09/800,610

(22) Filed: Mar. 8, 2001

(51) Int. Cl. H01L 23/10; H01L 23/043; H01L 23/06; H01L 23/495; H01L 23/36; H01L 23/427

(52) U.S. Cl. 257/669; 257/773; 257/522; 257/673

(57) ABSTRACT

A semiconductor chip is mounted over a flexible base plate. The base plate has an array of bubbles. Each bubble is coated with a metal tip, which is coupled by printed and leads bonds to the bonding pads of the chip. The metal tips are for making contacts to a printed circuit board when the package is mounted to a printed circuit board.

### BACKGROUND OF THE INVENTION

(1) Field of the Invention

This invention relates to semiconductor device package, particularly to integrated circuits package.

(2) Brief Description of the Related Art

In keeping pace with the rapid development of computer and communication equipment in recent years, semiconductor devices tends to emphasize portability and miniaturization. Semiconductor packages tends to be efficient, dense, light and thin. In addition, electronic packaging must preserve high reliability, high heat removal capability and cost effectiveness.

A popular packaging technique is the Micro Ball Grid Array (μBGA) for a single semiconductor chip as shown in FIG. 1A. A semiconductor chip 10 is mounted over an insulating base plate 14. The I/O bonding pads 12 for the semiconductor chip 10 are aligned along the four edges of the chip. These bonding pads 12 are coupled to the metal ball grid arrays 18 through lead bonds 16 and printed wires of the base plate 14.

FIG. 1B shows another arrangement of the bonding pads of the semiconductor chip 10. All the bonding pads 12 are aligned along two opposite side of the chip. These bonding pads 12 are coupled to the metal ball grid arrays 18 through lead bonds 16 and printed wires of the base plate 14.

The cross-sectional view along section AA′ of FIGS. 1A and 1B is shown in FIG. 1C. These bonding pads 12 are coupled to the metal ball grid arrays 18 through leads bonds 16 and printed wires of the base plate 14. A cushion 15 is placed between the chip 10 and the base plate 14 to cushion the mismatch in expansions of the chip 10 and the base plate 14 due to temperature variations. The structure is sealed in glue 19 for protection.

Because of the size of the balls of traditional BGA package, allowance must be made between adjacent balls and between the substrate and the motherboard. Thus, there is a limit to thickness and size of the package.

### SUMMARY OF THE INVENTION

An object of this invention is to provide a bubble grid array of I/O terminals on a flexible base. Another object of this invention is to improve the reliability of the array package. Still another object of this invention is to increase the density and to decrease the thickness of the grid array package.

These objects are achieved by replacing the metal ball grid array with bubble grid array. The bubbles are formed over a flexible base.

### BRIEF DESCRIPTION OF THE SEVERAL VIEWS OF THE DRAWINGS

FIG. 1A shows the bottom view of a prior art ball grid array; FIG. 1B shows another embodiment of a prior art ball grid array; FIG. 1C shows the cross-sectional view of FIGS. 1A and 1B.

FIG. 2A shows the bottom view of the bubble grid array based on the present invention; FIG. 2B shows another version of the bubble grid array; FIG. 2C shows the cross sectional view of FIGS. 2A and 2B.

FIG. 3A shows the cross-sectional view of a second embodiment of the bubble grid array; FIG. 3B shows a variation of FIG. 3A; FIG. 3C shows still another version of FIG. 3A.

FIG. 4A shows a 3-dimensional view of the base plate with lead bonds for the structure shown in FIG. 2A; FIG. 4B shows a 3-dimensional view of the package for the structure shown in FIG. 2B.

### DETAILED DESCRIPTION OF THE INVENTION

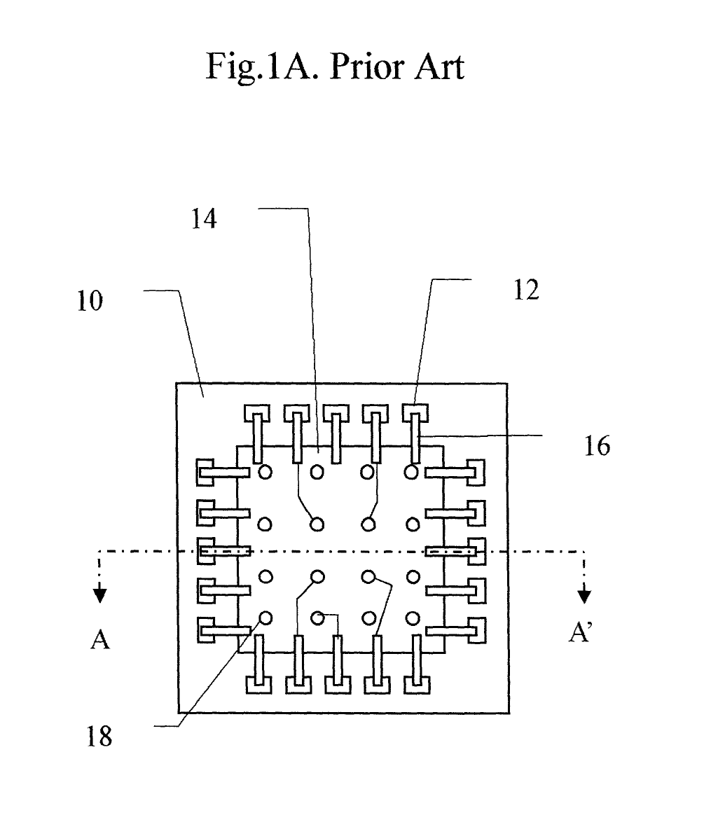

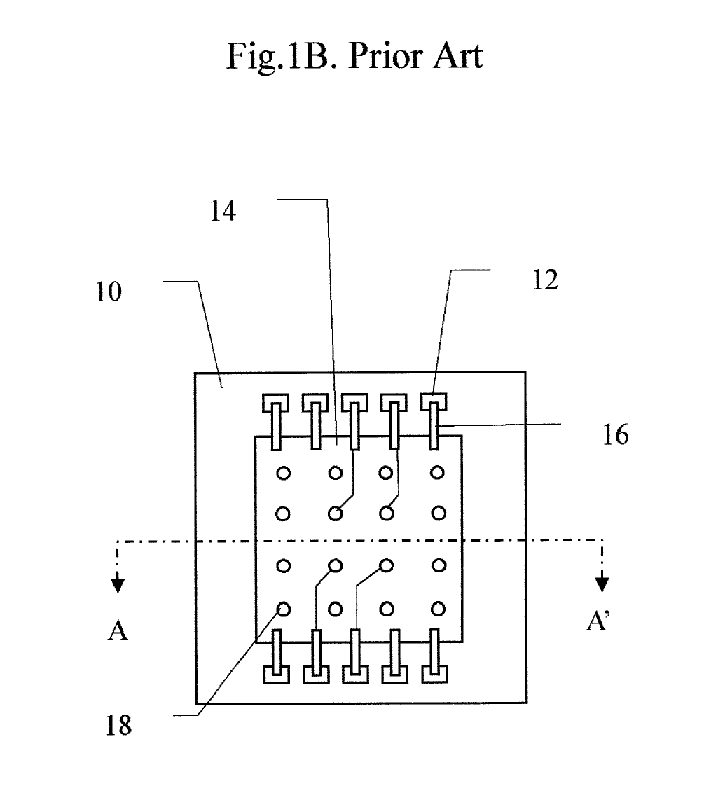

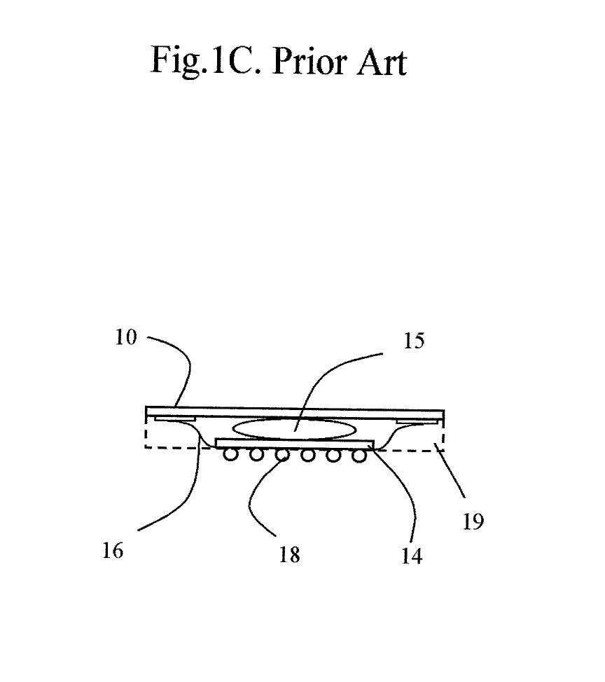

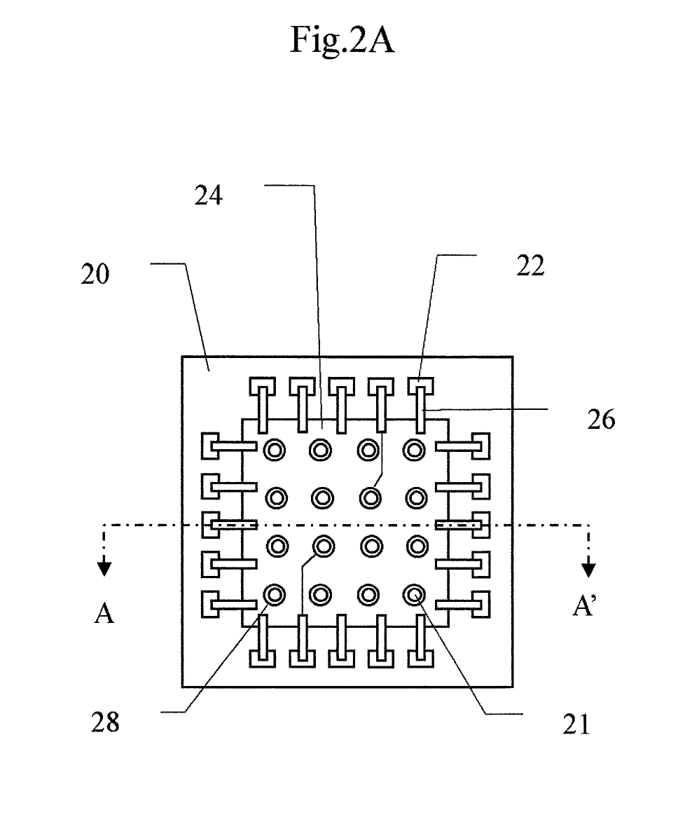

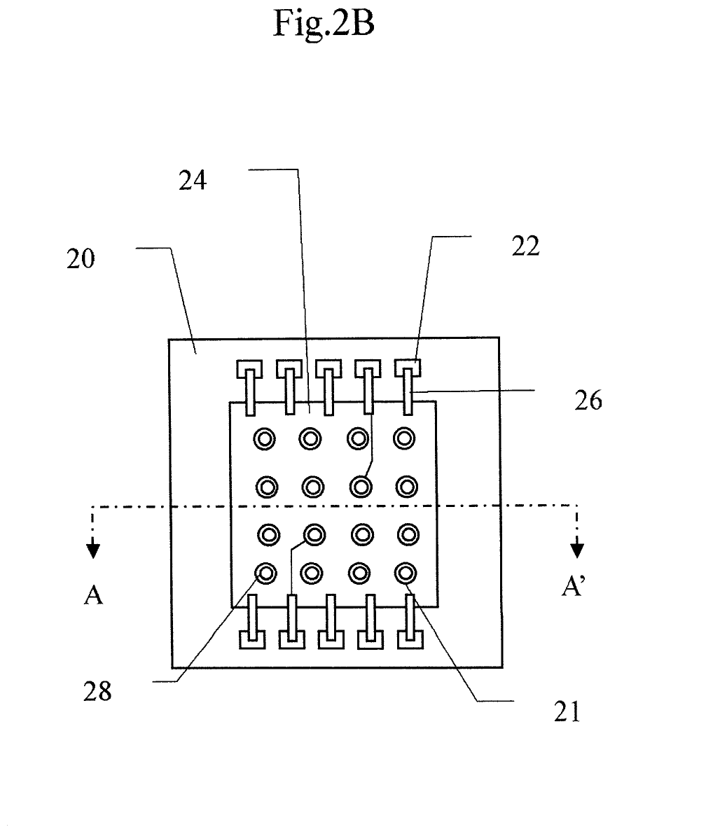

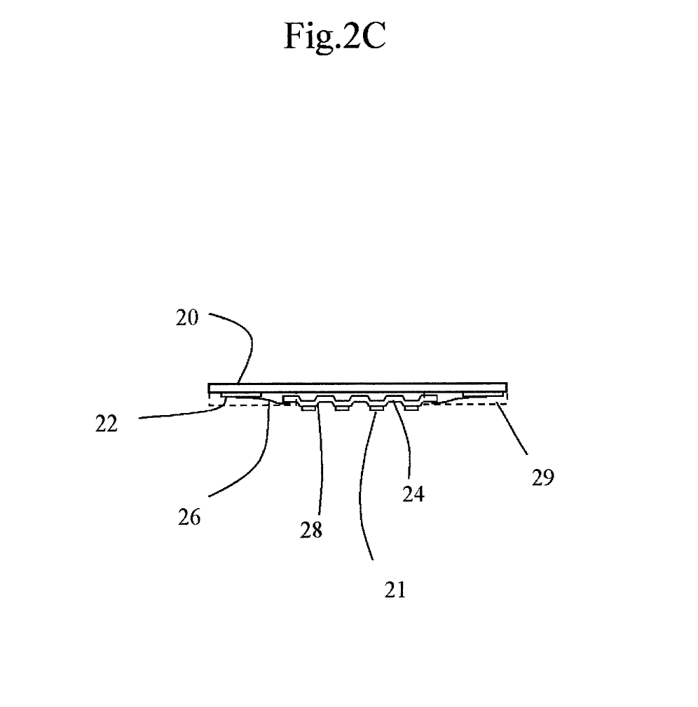

In this invention, bubble grid array on a flexible base is used for packaging a semiconductor chip instead of metal ball grid array. FIG. 1A shows the bottom view of the bubble grid array. A semiconductor chip 20 has bonding pads 22 aligned along the four edges of the chip. These bonding pads 22 are coupled to bubble grid arrays 28 through lead bonds 26 and printed wire of the base plate 24. The chip 20 is mounted over an insulating base plate 24. The bottom of the base plate 24 is not flat, but is corrugated with bubbles 28 as shown in the cross-sectional view FIG. 2C. The base plate 24 is of flexible material. The bubbles are formed by stamping from a mold to form conical bubbles few hundred microns deep. Each tip of the cones is coated with metal pads, where a printed wire 26 is coupled to a bonding pad 22. The bubbles are isolated from each other electrically. The metal pads can be coupled to a printed circuit board. The stamping process renders the process amenable to high density bubble array.

FIG. 2B shows a variation of FIG. 2A where the bonding pads 22 are aligned along two edges of the chip 20 with extension leads 26. The extension leads 26 are coupled by printed wires to the bubbles 28 on the base plate 24. The each bubble is coated with metal. The tips of the bubble cones are coupled to a printed circuit board.

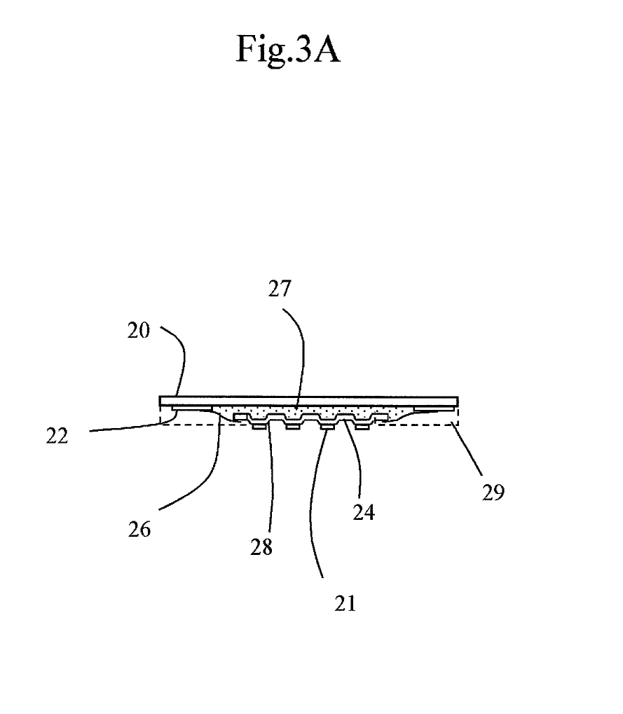

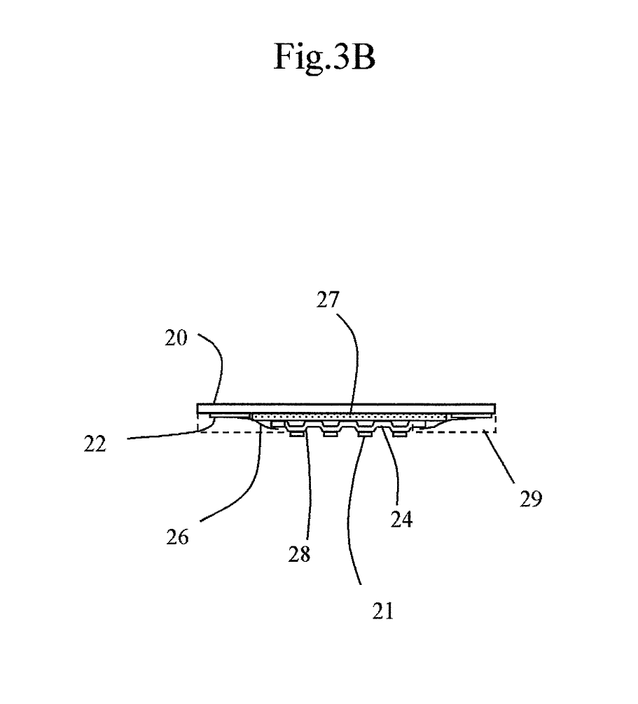

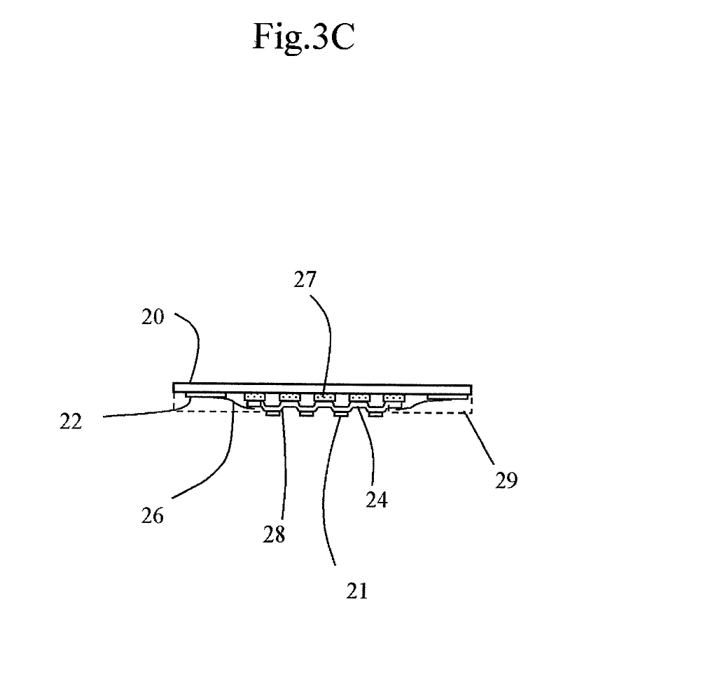

FIG. 3A shows a second embodiment of the bubble array. Between the bubble base plate 24 and the semiconductor chips is filled with a buffering glue 27 to improve heat conduction and to cushion the stress due to temperature expansion. The entire structure is then sealed in glue 29. The glue 29 protects the metal leads 26 and bonding pads 22, seals the chip against moisture and contamination, and improves the reliability of the package.

FIG. 3B shows a variation of FIG. 3A. The cushioning glue 27 has a planar lower surface, so that there are empty spaces between the tips of the bubbles 28 and the planar cushioning glue 27. Such an air space makes the base plate more flexible. A flexible base plate offers greater compliance to stress.

FIG. 3C shows another version of FIG. 3A. The cushioning glue 27 is individually mounted over the base between two adjacent bubbles 28. The structure provides an air space between adjacent bubbles and make the base plate more flexible.

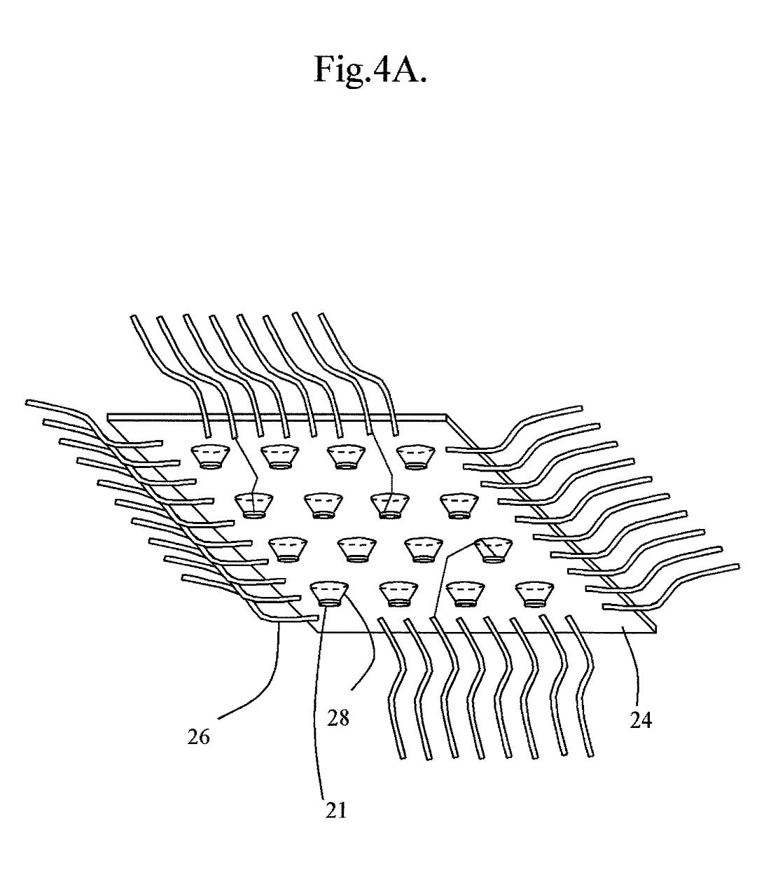

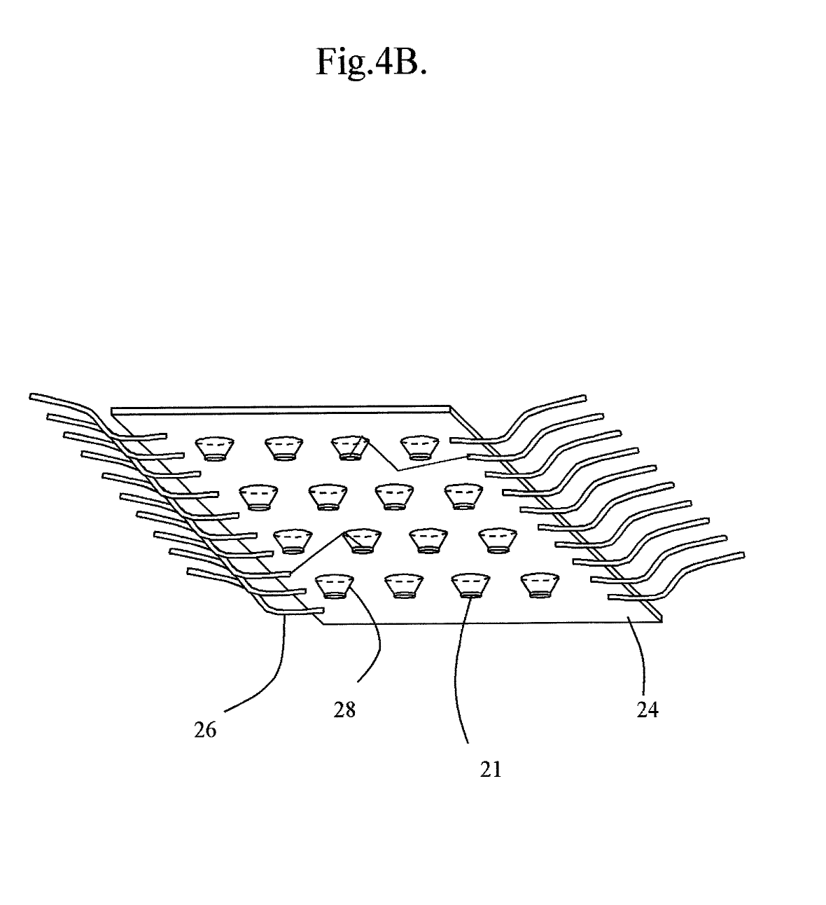

FIG. 4A shows the 3-dimensional bottom view of the bubble grid array shown in FIG. 2A. The extension leads 26 are coupled by printed wiring to the base of the individual bubble 28. The base plate 24 has an array of such bubbles 28. The tip 21 of each bubble cone can be coupled to a printed circuit board for circuit connection.

While the preferred embodiments have been described, it will be apparent to those skilled in the art that various modifications may be made in the embodiments without departing from the spirit of the present invention. Such modifications are all within the scope of this invention.

1. A semiconductor device package, comprising:
a semiconductor chip;
bonding pads aligned along at least one edge of said semiconductor chip;
a base plate underneath said semiconductor chip; and
an array of bubbles depressed in said base plate, each of said bubbles having a metal coating which is coupled to said bonding pads through printed wire and lead bonds of the base plate.

2. A semiconductor device package as described in claim 1, wherein said base plate is flexible.

3. A semiconductor device package as described in claim 1, wherein each one of said bubbles is less than 1 mm tall.

4. A semiconductor device package as described in claim 1, wherein said bubbles are of conical shape.

5. A semiconductor device package as described in claim 1, wherein said bonding pads are aligned along four sides of said chip.

6. A semiconductor device package as described in claim 1, wherein said bonding pads are aligned along two sides of said chip.

7. A semiconductor device package as described in claim 1, further comprising a cushion between the bottom surface of said chip and the top surface of said base plate.

8. A semiconductor device package as described in claim 7, wherein bottom of said cushion is planar, leaving air space between adjacent said bubbles.

9. A semiconductor device as described in claim 1, further comprising a cushion between said base plate and said semiconductor chip.

10. A semiconductor device package as described in claim 1, further comprising a glue to seal the lead bonds and said bonding pads.

11. A semiconductor device package as described in claim 1, wherein said bubbles are stamped from a molding press.
